(19) United States
(12) Patent Application Publication
(10) Pub. No.: US 2007/0061657 A1
(43) Pub. Date: Mar. 15, 2007

(54) Delay fault testing apparatus

(75) Inventors: Tsin-Yuan Chang, Hsinchu City (TW); Po-Lin Chen, Chung Pu Township (TW); Hao-Hsuan Chiu, Pan Chiao City (TW)

Correspondence Address: John S. Egbert;Egbert Law Offices, 412 Main Street, 7th Floor, Houston, TX, 77002, US

(73) Assignee: NATIONAL TSING HUA UNIVERSITY, Hsinchu (TW)

(21) Appl. No.: 11/203,381

(22) Filed: Aug. 12, 2005

(51) Int. Cl. G01R 31/28; G06F 11/00

(52) U.S. Cl. 714/742

(57) ABSTRACT

A delay fault testing apparatus includes a scan device having a first input for receiving a data to the core under test, an update device including an input electrically connected to a first output of the scan device, a first multiplexer including a first input electrically connected to the output of the scan device, a second input electrically connected to a first output of the update device, and an output electrically connected to an input of the core under test. The first input of the first multiplexer is switched to the output when a first control signal is asserted so that the output of the scan device is allowed to directly connect to the output of the first multiplexer to launch a transition by switching the first multiplexer rather than triggering an update event, which is restricted to be triggered in the time of a negative edge.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to a delay fault testing apparatus, and more particularly, to a delay fault testing apparatus which can deliver a testing pattern pair within a required timing specification.

### BACKGROUND OF THE INVENTION

With the advancement of the manufacture technology of semiconductor devices, more and more transistors can now be squeezed into a single chip. The same design was much larger several years ago. However, with the same design methodology, larger design takes more manpower and design time. Because of the increasing scale, it is harder for a design house to catch up the time-to-market. To reduce design time as well as lower the whole system cost, nowadays many systems are built by integrating existing cores in one single chip called SOC (System on Chip). These pre-designed and pre-verified cores may be CPUs, DSPs, media accelerators, memory, and mixed-signal modules. Although the highly-reusable design concept of core-based SOC could ease the problems of a large design, it creates new issues on the topic of manufacture test.

The DFT (Design-for-Test) circuit is specialized in transporting test data and test application. The core-based SOC is usually composed of TAM (Test Access Mechanism) for test data transportation and wrapper of each core to control/observe the I/O of the core. Nevertheless, the proposed test circuitries do not consider delay fault testing, which is more important than ever. With the shrinking process and higher timing specification, more timing defects make the uncertainty of performance in the product much larger. The purpose of delay fault testing is to make sure that the design-under-test meets timing specification. Cores in SOC will be partitioned into two groups, namely provider and consumer. Delay fault testing patterns are saved in both wrappers of provider and consumer. The IEEE P1500 Working Group is working toward a Standard for Embedded Core Test (SECT) since 1997 (see: http://grouper.ieee.org/groups/1500). The purpose of IEEE P1500 SECT is to standardize the interface between core provider and core user. It consists of two main parts: One part is the core test information transfer, and the other part defines scalable core test architecture to access and control CUT. However, the cooperation between provider and consumer limits parallel test scheduling and results in test time increment. The provider/consumer TAM model also conflicts with other TAM models that have less test application time.

### BRIEF SUMMARY OF THE INVENTION

The objective of the present invention is to provide a delay fault testing apparatus, which can deliver a pair of testing patterns within a required timing specification

In order to achieve the above-mentioned objective and avoid the problems of the prior art, the first embodiment of the present invention discloses a delay fault testing apparatus comprising a scan device including a first input for receiving a data to the core under test, an update device including an input electrically connected to a first output of the scan device, a first multiplexer including a first input electrically connected to the first output of the scan device, a second input electrically connected to an output of the update device, and an output electrically connected to an input of the core under test. The first input of the first multiplexer is switched to the output when a first control signal is asserted so that the output of the scan device is allowed to directly connect to the output of the first multiplexer, i.e., the input of the core under test, to launch a transition by switching the first multiplexer rather than triggering an update event, which is restricted to be triggered at the time of a negative edge of a wrapper clock.

The second embodiment of the present invention discloses a delay fault testing apparatus comprising a scan device including a first input for receiving a data to the core under test, a second multiplexer including a first input electrically connected to a first output of the scan device, an update device including an input electrically connected to an output of the second multiplexer, a first multiplexer including a first input electrically connected to the first output of the scan device, a second input electrically connected to an output of the update device, and an output electrically connected to an input of the core under test. The second multiplexer further includes a second input for receiving a testing signal, and the output of the update device is capable of being electrically connected to another delay fault testing apparatus. The second input of the second multiplexer is switched to the output when a second control signal is asserted so that a testing pattern pair can be shifted in/out the delay fault testing apparatus simultaneously.

The third embodiment of the present invention discloses a delay fault testing apparatus for a core under test comprising a scan device including a first input for receiving a data from the core under test, an update device including an input electrically connected to a first output of the scan device, a first multiplexer including a first input electrically connected to the first output of the scan device, a second input electrically connected to an output of the update device, an output electrically connected to an test sink such as a data analyzer, a second multiplexer including an output electrically connected to the first input of the scan device and a first input electrically connected to an output of the core under test, and a capture device including an output electrically connected to a second input of the second multiplexer and an input electrically connected to the output of the core under test. The second input of the second multiplexer is switched to the output when a first control signal is asserted so that a fault effect from the core under test is captured into the capture device, and fault effect will be transferred to the scan device when a capture event raises.

### BRIEF DESCRIPTION OF THE SEVERAL VIEWS OF THE DRAWINGS

The objectives and advantages of the present invention will become apparent upon reading the following description and upon reference to the accompanying drawings.

FIG. 1 and FIG. 2 are schematic views of illustrations of the application of a delay fault testing apparatus to a core under test according to one embodiment of the present invention.

FIG. 3 is a schematic view of an illustration showing a delay fault testing apparatus according to one embodiment of the present invention.

FIG. 4 is a schematic view of an illustration showing a testing pattern pair.

FIG. 5 is another schematic view of an illustration showing the application of a delay fault testing apparatus to a core under test according to one embodiment of the present invention.

FIG. 6 is a schematic view of an illustration showing the detailed configuration of the update device according to the present invention.

FIG. 7 is still another schematic view of an illustration showing the detailed configuration of the scan device according to the present invention.

FIG. 8 is a schematic view of an illustration showing the modification of the wrapper instruction register (WIR) according to the present invention.

FIG. 9 is yet another schematic view of an illustration showing the waveform of the pattern application according to the present invention.

FIG. 10 is a schematic view of an illustration showing one of the schemes of a clock-gating circuit according to the prior art.

FIG. 11 is a schematic view of an illustration showing a clock-gating circuit according to one embodiment of the present invention.

FIG. 12 is another schematic view of an illustration showing a clock cell according to one embodiment of the present invention.

FIG. 13 is a schematic view of an illustration showing the detailed state transition diagrams of the clock cell according to one embodiment of the present invention.

FIG. 14 is a schematic view of an illustration showing a clock configuration for SOC according to one embodiment of the present invention.

### DETAILED DESCRIPTION OF THE INVENTION

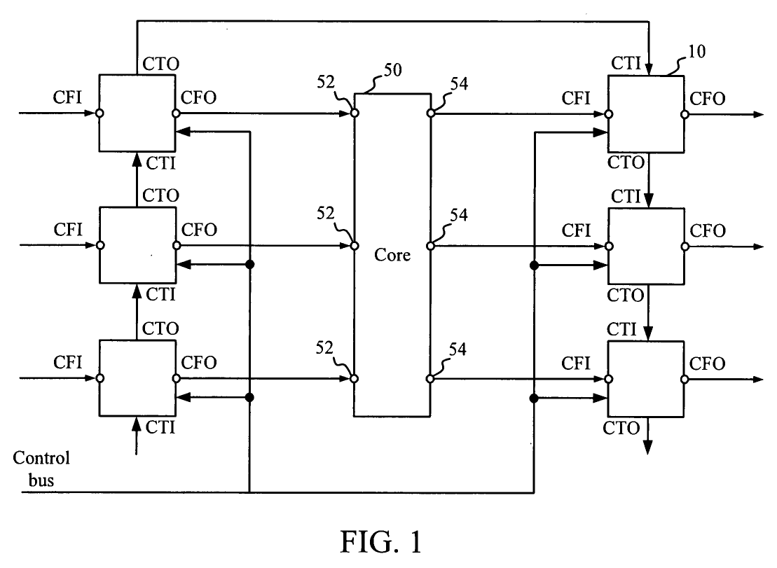

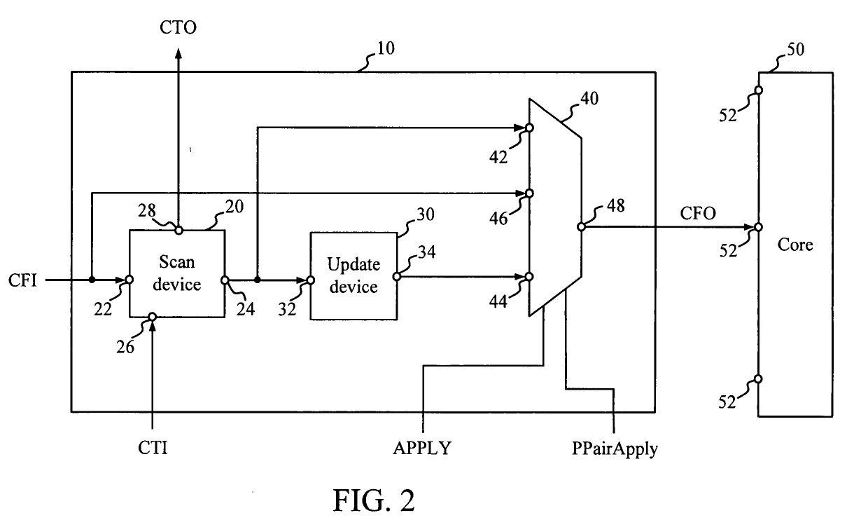

FIG. 1 and FIG. 2 illustrate the application of a delay fault testing apparatus 10 to a core under test (CUT) 50 according to one embodiment of the present invention. Particularly, the function of the delay fault testing apparatus 10 corresponds to the wrapper boundary register (WBR) of IEEE P1500. The delay fault testing apparatus 10 comprises a scan device 20 including a first input 22 for receiving a data to the CUT 50, an update device 30 including an input 32 electrically connected to a first output 24 of the scan device 20, a first multiplexer 40 including a first input 42 electrically connected to the first output 24 of the scan device 20, a second input 44 electrically connected to an output 34 of the update device 30, a third input 46 electrically connected to the first input 22 of the scan device 20 for receiving the data, and an output 48 electrically connected to an input 52 of the CUT 50.

Since the first multiplexer 40 includes the first input 42 electrically connected to the first output 24 of the scan device 20, a core function input (CFI) will become a core function output (CFO) from the output 48, to the CUT 50 directly from the scan device 20 rather than via the update device 30. The scan device 20 may further include a second input 26 for receiving a test signal, i.e., a core test signal input (CTI), and a second output 28 for shifting the core testing signal (CTO) as an output to another delay fault testing apparatus.

The first input 42 of the first multiplexer 40 is switched to the output 48 when a first control signal, i.e., PPairApply, is asserted so that the output 24 of the scan device 20 is allowed to directly connect to the output 48 of the first multiplexer 40, i.e., to the input 52 of the CUT 50, to launch a transition by switching the first multiplexer 40 rather than triggering an update event, which is restricted to be triggered at the time of a negative edge of a wrapper clock.

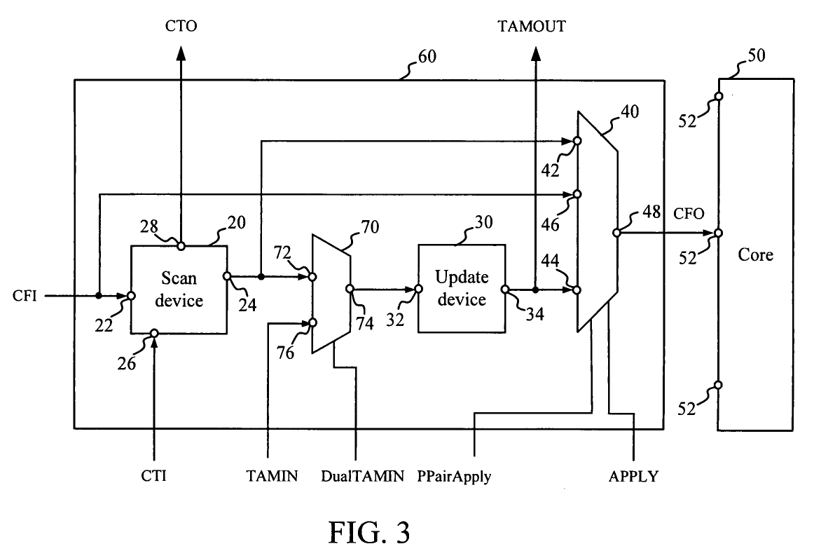

FIG. 3 illustrates a delay fault testing apparatus 60 according to one embodiment of the present invention. The delay fault testing apparatus 60 comprises a scan device 20 including a first input 22 for receiving a data to the CUT 50, a second multiplexer 70 including a first input 72 electrically connected to a first output 24 of the scan device 20, an update device 30 including an input 32 electrically connected to an output 74 of the second multiplexer 70, a first multiplexer 40 including a first input 42 electrically connected to the first output 24 of the scan device 20, a second input 44 electrically connected to an output 34 of the update device 30, and an output 48 electrically connected to an input 52 of the CUT 50. The second multiplexer 70 may further include a second input 76 for receiving a testing signal such as the core testing signal, i.e., TAMIN, and the output 34 of the update device 30 is capable of being electrically connected to another delay fault testing apparatus to shift the core testing signal as an output, i.e., TAMOUT.

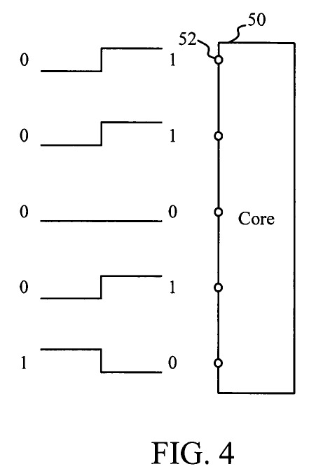

FIG. 4 illustrates a testing pattern pair. During test application, pattern shifting is time-consuming. In a design with multiple scan chains, the longest scan chain determines the pattern shifting time, and the length of the testing pattern pair has to be considered as well. Particularly, pattern pair shifting time dominates when the design is relatively small or has short scan chains. One of trade-offs to the pattern application time is adding an additional signal for pattern pair. The second input 76 of the second multiplexer 70 is switched to the output 74 when a second control signal, i.e., DaulTAMIN is asserted so that the delay fault testing apparatus 60 can use CTI/CTO path to shift in/out one pattern of the testing pattern pair and use TAMIN/TAMOUT path to shift in/out another pattern of the testing pattern pair simultaneously.

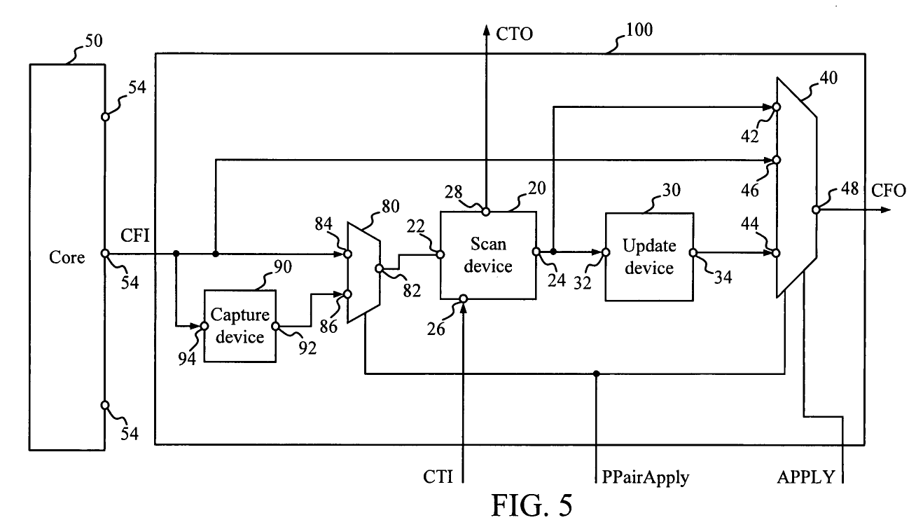

FIG. 5 illustrates the application of a delay fault testing apparatus 100 to the CUT 50 according to one embodiment of the present invention. The delay fault testing apparatus 100 comprises a scan device 20 including a first input 22 for receiving a data, such as core function input (CFI), from the CUT 50, an update device 30 including an input 32 electrically connected to a first output 24 of the scan device 20, a first multiplexer 40 including a first input 42 electrically connected to the first output 24 of the scan device 20, a second input 44 electrically connected to an output 34 of the update device 30, and an output 48 electrically connected to an test sink such as a data analyzer, a second multiplexer 80 including an output 82 electrically connected to the first input 22 of the scan device 20 and a first input 84 electrically connected to an output 54 of the CUT 50, and a capture device 90 including an output 92 electrically connected to a second input 86 of the second multiplexer 80 and an input 94 electrically connected to the output 54 of the CUT 50. The second input 86 of the second multiplexer 80 is switched to the output 82 when a first control signal, i.e., PPairApply is asserted. Preferably, the capture device 90 is clocked by the system clock in order to time launch-capture interval by the same system clock. When PPairApply signal is asserted, it enables the delay fault testing apparatus 100 to capture the fault effect using the capture device 90 and data held in the capture device 90 is selected. Next, when CAPTURE event is raised, fault effect captured in the capture device 90 will be transferred into the scan device 20. Finally, it will be shifted out of the delay fault testing apparatus 100 to the test sink.

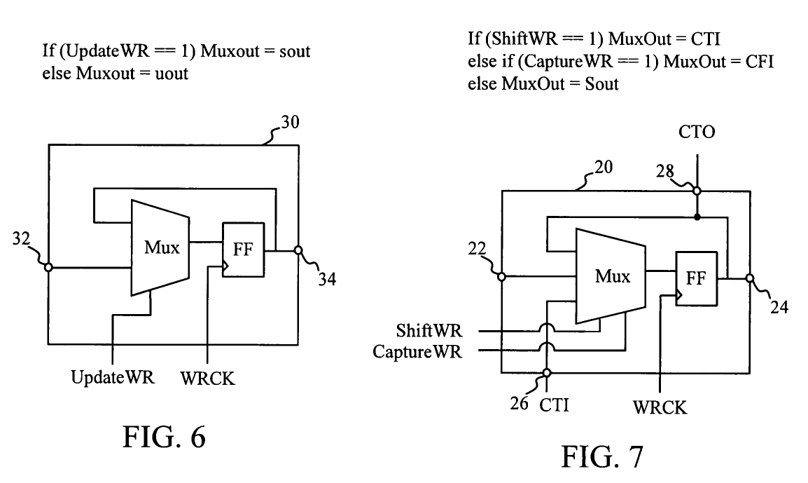

FIG. 6 illustrates the detailed configuration of the update device 30 and FIG. 7 illustrates the detailed configuration of the scan device 20. The update device 30 consists of one flip-flop (FF) and one multiplexer (Mux), wherein the output of the multiplexer is controlled by a control signal, i.e., UpdateWR. The scan device 20 also consists of one flip-flop and one multiplexer, wherein the output of the multiplexer is controlled by two control signals, i.e., ShiftWR and CaptureWR. Preferably, the capture device 90 is a flip-flop clocked by the system clock (NCK).

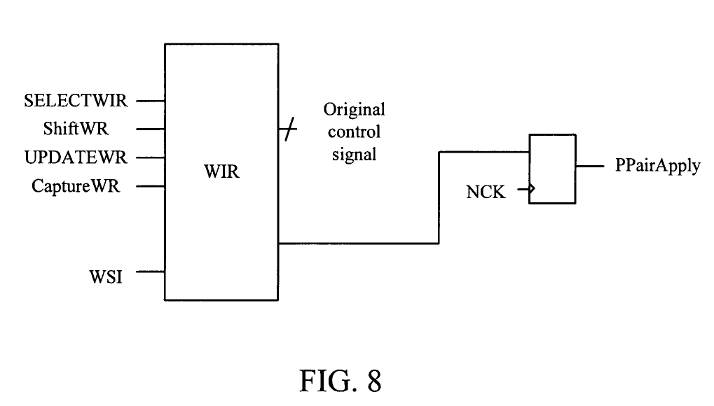

FIG. 8 illustrates the modification of the wrapper instruction register (WIR) according the present invention. The WIR is the main controller of a wrapper according to IEEE P1500. For delay fault testing, a new instruction is added to WIR circuitry, and an output control signal is added for modifying WBR as well. The newly-proposed instruction will configure wrapper into DELTEST mode, which will assert PPaireApply to launch transition. Once the wrapper is programmed to DELTEST mode, PPairApply is controlled by CaptureWR and transition could be triggered by test controller in SOC. However, to meet the timing specification (constraints) for delay fault testing that specifies the interval between launch and capture, transition of the pattern pair must be triggered very precisely.

Under the architecture of IEEE P1500 wrapper, launch command is sent on the rising edge of wrapper while the fault effect is captured on the rising edge of the system clock. As a result of indeterminable difference of clock latency, it is not reliable to launch transition through wrapper clock. The modified transition-launching control signal is gated by a flip-flop, which is clocked by the system clock (NCK) rather than be transparent to all the WBRs. In this way, the launch event is synchronized to the system clock. The path after gated flip-flop could be treated as a normal functional path in both synthesis and P&R phase instead of false path and can be constrained to meet the timing specification. A proposed sequence of delay fault testing for the modified wrapper instruction register is shown below:
1. Sending test instruction to the WIR and then update the instruction to take effect (Wrapper Test Sequence, Phase 1);
2. Shifting in first pattern of PI;
3. Raising UPDATE event to load first pattern to UPDATE register (Wrapper Test Sequence, Phase 2);
4. Shifting in second pattern of PI;
5. Asserting Capture signal of WIR and trigger wrapper clock once to release synchronization register;
6. Triggering normal clock to launch a transition from synchronization register;
7. Triggering normal clock again to capture fault effect in the specified time interval.

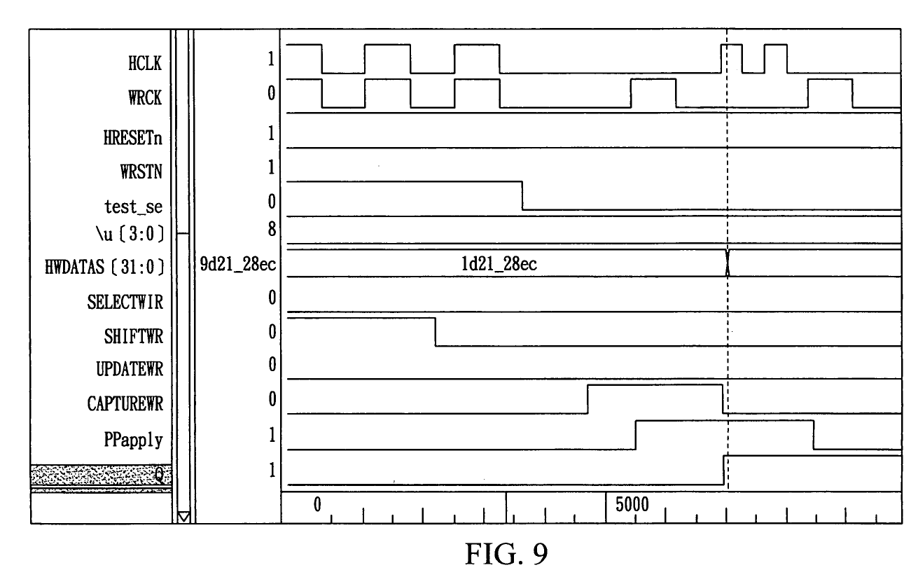

FIG. 9 shows the waveform of pattern application. The data of scan chains of the CUT is shifted in/out during pattern pair shifting. The total shift length is either the maximum length of scan chains or the sum of the length of the pattern pair. The test controller of the SOC is capable of generating the test application sequence for delay fault testing. Note that signal Q is PPApply after resynchronization. The HWDATA as core input is changed by launch clock pulse.

In a SOC design, cores triggered by the same clock tree will act at the same pace. However, when delay fault testing is applied to a core, clock rate switches between test clock for shift in/out operations and functional clock for launch/capture operations. Over-clocking shift operation causes too much power dissipation and may damage the cores. The other concern is that most of the scan chains are treated as non-functional paths and not constrained by functional timing specification. Therefore, the data of the chains corrupts when operated at functional speed.

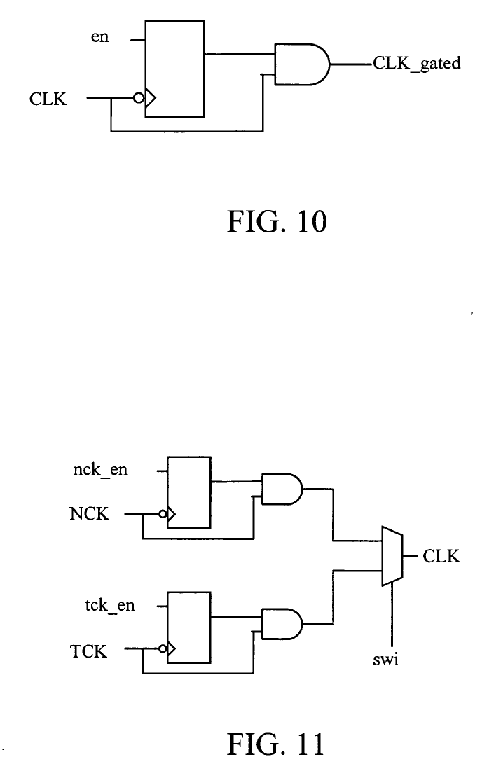

FIG. 10 shows one of the schemes of a clock-gating circuit according to the prior art, and FIG. 11 illustrates a clock-gating circuit according to one embodiment of the present invention. Here, in order to prevent output clock from glitch, enable signal (en) is gated by a flip-flop. Note that the flip-flop is triggered on falling edge of the clock (CLK), so modes are only changed on the falling edge to generate the gated clock (CLK_gated). The circuit is extended to select one clock from normal clock (NCK) and test clock (TCK). Each of the clock sources has one copy of the original gating circuit, and output clock signal is switched by a multiplexer. As shown in FIG. 11, by controlling signal, i.e., nck_en, tck_en, and swi, the present clock gating circuit can disable, turn on, and switch output clock from normal clock to test clock, and vice versa.

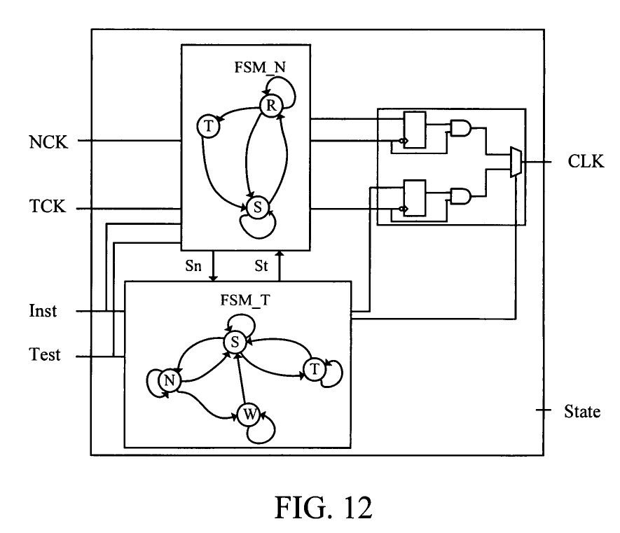

FIG. 12 illustrates a clock cell according to one embodiment of the present invention. The clock cell for individual core consists of a clock switching circuit and a controller. Basically, the controller of the gating circuit is clocked by a test clock. However, in order to count two pulses from free-running normal clock, a finite state machine (FSM) clocked by normal clock for nck_en is needed. Thus, the controller is composed of two FSMs triggered by different clocks. FSM_T at test clock domain controls tck_en and swi whereas FSM_N at normal clock domain generates nck_en. The controller is configured by the Test and Inst signals. Inst means input instruction, and Test tells CTRL_CELL if it is in delay fault testing mode. The State output is the concatenation of states of FSM_N and FSM_T.

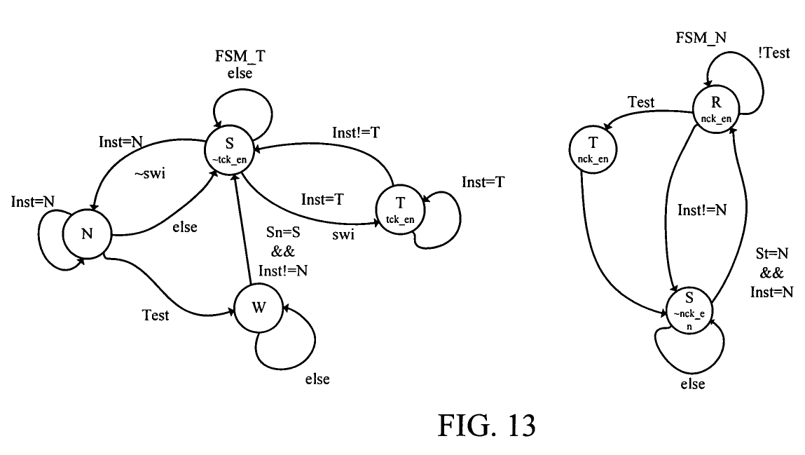

FIG. 13 illustrates the detailed state transition diagrams. Signals St and Sn represent current state of FSM_T and FSM_N, respectively. The controller supports three instructions: named NORMALCLK, TESTCLK, and STALL. Output clock is switched to test clock when TESTCLK is received. The STALL instruction “silences” core clock. When NORMALCLK is received, the actual operation depends on Test signal. First, FSM_T goes to state S (Stall), and then FSM_N is enabled to change to state R (Run). If Test is asserted, FSM_N goes back to state S through state T (Test). At the same time, the core receives exactly two pulses from normal clock source. Changing to state W (Wait) immediately, FSM_T does not go back to state S until the generation of both clock pulses is completed, and the instruction is no longer NORMALCLK. A waiting interval can be defined in advance by setting Inst to NORMALCLK in terms of test clock cycle. The purpose is to guarantee there is no ambiguity in the number of shift operation. If Test is de-asserted, FSM_N stays at state R and generates consecutive clock pulses from normal clock source. FSM_N and FSM_T are both back to state S directly, when instruction is no longer NORMALCLK. Note that signal swi is solo switched at the edges from states S to N or from states S to T. Since in state S both of the clock sources are disabled, switching the source of clock at the edges starting from state S will keep output clock from glitch. Also note that although the free-running normal clock cannot shut down/restore very precisely since there is no relationship between two clocks, the test clock can be controlled without any ambiguity. This is important because the number of shift operation must be exactly the same as maximum length of the scan chains.

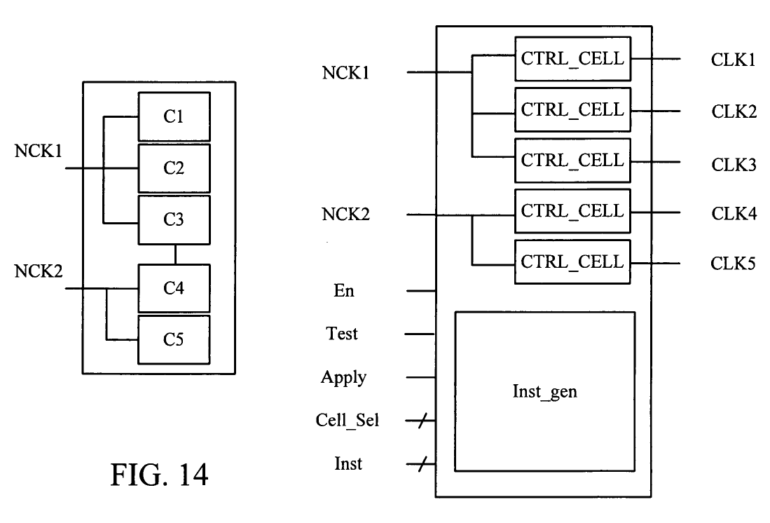

FIG. 14 illustrates a clock configuration for SOC according to one embodiment of the present invention. The whole proposed clock controller consists of CTRL_CELLs described above and other circuitry to generate instructions for each CTRL_CELL. The most important function of the controller is to stall other cores in the same clock tree, when the core-under-test is in launch-capture phase. Core1 to Core3 are clocked by NCK1 while Core4 and Core5 are clocked by NCK2. If En goes low, clock controller is disabled, and every core received normal clock signal. The Test signal tells whether it is in delay fault testing mode or not and is directly connected to each CTRL_CELL.

If Test is asserted, the core-under-test is determined by a signal Cell_Sel and launch-capture event is applied by APPLY signal. If the Cell_Sel indicates that Core4 finishes shift operations first, during the time that Apply is asserted, the CTRL_CELL of Core4 receives NORMALCLK instruction while CTRL_CELL of Core5 receives STALL instruction. When Apply signal goes low, both Core4 and Core5 receive TESTCLK to restore to shift operation. When clock controller is no longer in delay fault testing mode, each CTRL_CELL is freely chosen by Cell_Sel, and receives instruction from Inst and updates by Apply signal, so the unused cores can be shut down for power reduction not only in test mode but in normal functional mode as well.

The above-described embodiments of the present invention are intended to be illustrative only. Numerous alternative embodiments may be devised by those skilled in the art without departing from the scope of the following claims.

We claim:

1. A delay fault testing apparatus for a core under test, comprising:
a scan device being comprised of a first input for receiving a data to the core under test;
an update device being comprised of an input electrically connected to a first output of the scan device; and
a first multiplexer being comprised of a first input electrically connected to the first output of the scan device, a second input electrically being connected to an output of the update device, and an output being electrically connected to an input of the core under test.

2. The delay fault testing apparatus of claim 1, wherein the first input of the first multiplexer is switched to the output when a first control signal is asserted to a transition.

3. The delay fault testing apparatus of claim 1, wherein the first multiplexer is further comprised of a third input electrically connected to the first input of the scan device for receiving the data to the core under test.

4. The delay fault testing apparatus of claim 1, wherein the scan device is further comprised of a second input for receiving a test signal and a second output for shifting the testing signal to another delay fault testing apparatus.

5. A delay fault testing apparatus for a core under test, comprising:
a scan device being comprised of a first input for receiving a data to the core under test;
a second multiplexer being comprised of a first input electrically connected to a first output of the scan device;
an update device being comprised of an input electrically connected to an output of the second multiplexer; and
a first multiplexer being comprised of a first input electrically connected to the first output of the scan device, a second input being electrically connected to an output of the update device, and an output being electrically connected to an input of the core under test.

6. The delay fault testing apparatus of claim 5, wherein the second multiplexer is further comprised of a second input for receiving a testing signal, the first output of the update device being electrically connected to another delay fault testing apparatus.

7. The delay fault testing apparatus of claim 6, wherein the second input of the second multiplexer is switched to the output when a second control signal is asserted.

8. The delay fault testing apparatus of claim 5, wherein the first input of the first multiplexer is switched to the output when a first control signal is asserted to a transition.

9. The delay fault testing apparatus of claim 5, wherein the first multiplexer is further comprised of a third input coupled with the first input of the scan device for receiving the data to the core under test.

10. The delay fault testing apparatus of claim 5, wherein the scan device is further comprised of a second input for receiving the test signal and a second output for shifting the testing signal to another delay fault testing apparatus.

11. A delay fault testing apparatus for a core under test, comprising:
a scan device being comprised of a first input for receiving a data from the core under test;
an update device being comprised of an input electrically connected to a first output of the scan device;
a first multiplexer being comprised of a first input electrically connected to the first output of the scan device, a second input electrically connected to an output of the update device, and an output electrically connected to an test sink;
a second multiplexer being comprised of an output electrically connected to the first input of the scan device and a first input electrically connected to an output of the core under test; and
a capture device being comprised of an output electrically connected to a second input of the second multiplexer and an input electrically connected to the output of the core under test.

12. The delay fault testing apparatus of claim 11, wherein the first input of the first multiplexer is switched to the output and the second input of the second multiplexer is switched to the output when a first control signal is asserted to a transition.

13. The delay fault testing apparatus of claim 11, wherein the first multiplexer is further comprised of a third input electrically connected to the first input of the second multiplexer for receiving the data from the core under test.

14. The delay fault testing apparatus of claim 11, wherein the scan device is further comprised of a second input for receiving a test signal and a second output for shifting the testing signal to another delay fault testing apparatus.
